(19) United States
(12) Patent Application Publication
(10) Pub. No.: US 2011/0065249 A1
(43) Pub. Date: Mar. 17, 2011

(54) Method of manufacturing a semiconductor device in which an increase in area of the semiconductor device is suppressed

(75) Inventor: Hidekazu Egawa, Tokyo (JP)

(73) Assignee: Elpida Memory, Inc., Tokyo (JP)

(21) Appl. No.: 12/805,016

(22) Filed: Jul. 7, 2010

(30) Foreign Application Priority Data
Sep. 14, 2009 (JP) 2009-211387

(51) Int. Cl. H01L 21/336

(52) U.S. Cl. 438/289; 257/E21.409

(57) ABSTRACT

A method of manufacturing a semiconductor device includes: performing, in a case of manufacturing a first semiconductor device which operates by a first power supply voltage, at least one step from among channel ion implantation, gate oxide film formation, and gate electrode patterning according to a process of forming an element which operates with the first power supply voltage; performing, in a case of manufacturing a second semiconductor device which operates by a second power supply voltage, at least one step from among the channel ion implantation, the gate oxide film formation, and the gate electrode patterning according to a process of forming an element which operates with the second power supply voltage; and commonly performing at least diffusion region formation in the case of manufacturing the first semiconductor device and in the case of manufacturing the second semiconductor device.

### This application is based upon and claims the benefit of priority from Japanese Patent Application No. 2009- 211387 filed on Sep. 14, 2009, the content of which is incorporated by reference.

### BACKGROUND OF THE INVENTION

1. Field of the Invention

The present invention relates to a method of manufacturing a semiconductor device, and more particularly, to a method of manufacturing a semiconductor device in accordance with specifications of a power supply voltage.

2. Description of Related Art

In recent years, along with the progress in manufacturing semiconductor or the like, semiconductor devices which can operate with a lower voltage have been developed, with the result that semiconductor devices which operate with various power supply voltages have appeared. Consequently, the requirement is to manufacture an individual semiconductor device on the assumption that the semiconductor device is to be connected to another semiconductor device which operates with a plurality of power supply voltages. The semiconductor device which is assumed to be connected to another semiconductor device which operates with the plurality of power supply voltages, as described above, is described in, for example,

Meanwhile, in manufacturing the semiconductor device which is assumed to be connected to another semiconductor device which operates with the plurality of power supply voltages, it is necessary to manufacture a semiconductor device including an output circuit which operates with power supply voltages that respectively correspond to the plurality of power supply voltages. An example of the method of manufacturing the semiconductor device as described above includes individually designing the semiconductor devices each including an output circuit which operates with different power supply voltages and further manufacturing each of the designed semiconductor devices in an individual process.

However, in the case of individually designing and manufacturing the plurality of semiconductor devices in which only the power supply voltages of the output circuits are different, there arises a problem in which the cost of development and the cost of manufacturing for the semiconductor devices increase. As a specific example of the plurality of semiconductor devices as described above, semiconductor devices in which only the characteristics of a transistor which forms the output circuit are different can be conceived.

In addition, another example of the above-mentioned method includes a wire option method of forming, within one semiconductor device, a plurality of the output circuits which operate with the power supply voltages respectively corresponding to the plurality of power supply voltages and switching by a wiring process in accordance with the plurality of required power supply voltages. However, this method requires that an output circuit, which will not operate, is formed within one semiconductor device, and hence there arises a problem in which the area of the semiconductor device increases. Particularly, the transistor of the output circuit needs to have a high current drive capability in order to drive an external apparatus connected via an external wiring on the far side thereof, and therefore has a large size, which makes the area of the semiconductor device larger.

### SUMMARY

In one embodiment, there is provided a method of manufacturing a semiconductor that includes: performing, in a case of manufacturing a first semiconductor device which operates by being supplied with a first power supply voltage from an outside, at least one step from among channel ion implantation, gate oxide film formation, and gate electrode patterning according to a process of forming an element which operates with the first power supply voltage; performing, in a case of manufacturing a second semiconductor device which operates by being supplied with a second power supply voltage from the outside, at least one step from among the channel ion implantation, the gate oxide film formation, and the gate electrode patterning according to a process of forming an element which operates with the second power supply voltage; and commonly performing at least diffusion region formation in the case of manufacturing the first semiconductor device and in the case of manufacturing the second semiconductor device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram illustrating a structural example of a semiconductor memory device according to an exemplary embodiment;

FIG. 2 is a flowchart illustrating a procedure for a method of manufacturing the semiconductor memory device according the present exemplary embodiment;

FIG. 3 are plan views and cross sectional views of the semiconductor memory device, for describing a diffusion region formation step;

FIG. 4A are cross sectional views for describing a channel ion implantation step in a semiconductor memory device having a specification of VDD=1.8 V;

FIG. 4B are cross sectional views for describing the channel ion implantation step in a semiconductor memory device having a specification of VDD=1.5 V;

FIG. 5 are plan views and cross sectional views of the semiconductor memory device, for describing a gate trench formation step;

FIG. 6A are plan views and cross sectional views for describing a gate oxide film formation step in the semiconductor memory device having the specification of VDD=1.8 V;

FIG. 6B are plan views and cross sectional views for describing the gate oxide film formation step in the semiconductor memory device having the specification of VDD=1.5 V;

FIG. 7A are plan views and cross sectional views for describing a gate material lamination/ion implantation step in the semiconductor memory device having the specification of VDD=1.8 V;

FIG. 7B are plan views and cross sectional views for describing the gate material lamination/ion implantation step in the semiconductor memory device having the specification of VDD=1.5 V;

FIG. 8A are plan views and cross sectional views for describing a gate electrode patterning step in the semiconductor memory device having the specification of VDD=1.8 V;

FIG. 8B are plan views and cross sectional views for describing the gate electrode patterning step in the semiconductor memory device having the specification of VDD=1.5 V;

FIG. 9A are plan views and cross sectional views for describing a source/drain formation step in the semiconductor memory device having the specification of VDD=1.8 V;

FIG. 9B are plan views and cross sectional views for describing the source/drain formation step in the semiconductor memory device having the specification of VDD=1.5 V;

FIG. 10A are plan views and cross sectional views for describing a contact formation step in the semiconductor memory device having the specification of VDD=1.8 V;

FIG. 10B are plan views and cross sectional views for describing the contact formation step in the semiconductor memory device having the specification of VDD=1.5 V;

FIG. 11A is a schematic view illustrating a positional relation between a gate electrode and a contact in a power supply voltage dependent element having the specification of VDD=1.8 V;

FIG. 11B is a schematic view illustrating a positional relation between a gate electrode and a contact in a power supply voltage dependent element having the specification of VDD=1.5 V;

FIG. 11C is a schematic view illustrating a positional relation between a gate electrode and a contact in an element which is common to both the specification of VDD=1.8 V and the specification of VDD=1.5 V;

FIG. 12A is a plan view illustrating a case where a gate width of a transistor is long;

FIG. 12B is a cross sectional view illustrating the transistor of FIG. 12A;

FIG. 13A is a plan view illustrating a transistor with a gate width shorter than that of the transistor of FIG. 12A; and

FIG. 13B is a cross sectional view illustrating the transistor of FIG. 13A.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

A structure of a semiconductor device according to an exemplary embodiment is described. The present exemplary embodiment describes a case where the semiconductor device is a semiconductor memory device which is typified by a DRAM (Dynamic Random Access Memory).

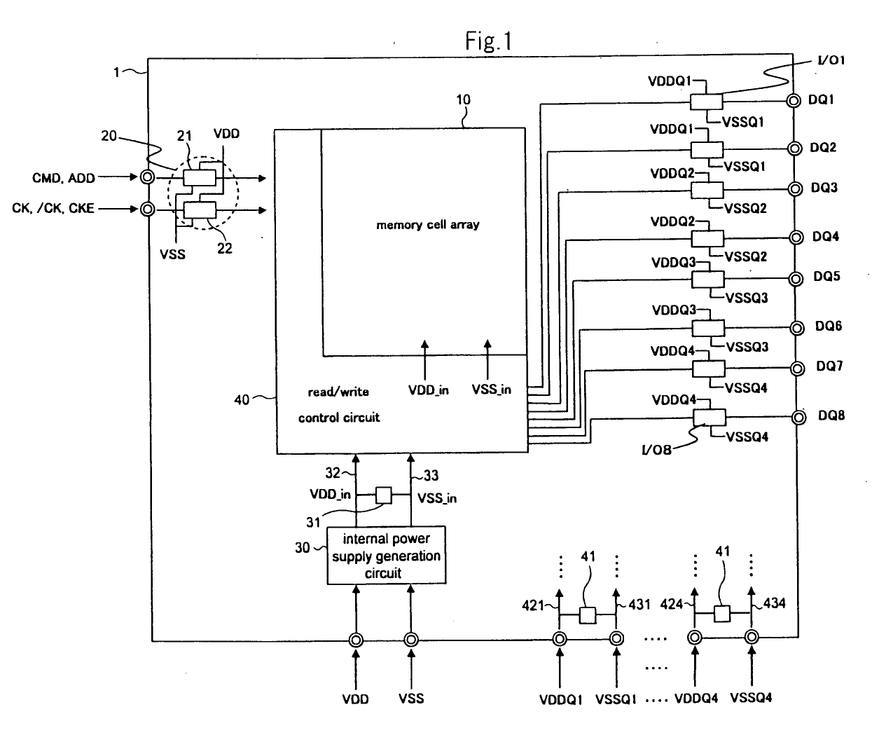

FIG. 1 is a block diagram illustrating a structural example of semiconductor memory device according to the present exemplary embodiment. As illustrated in FIG. 1, semiconductor memory device 1 includes memory cell array 10, input circuit 20, internal power supply generation circuit 30, read/write control circuit 40, and data input/output circuits I/O1 to I/O8.

Memory cell array 10 includes memory cells (not shown). The memory cells included in memory cell array 10 are each formed of a common element which is not dependent on specifications of a power supply voltage applied from the outside. Memory cell array 10 is connected to read/write control circuit 40, and each of the memory cells included in memory cell array 10 is supplied with an internal power supply voltage from internal power supply generation circuit 30 via read/write control circuit 40.

Input circuit 20 includes command/address input circuit 21 and clock input circuit 22. Each of command/address input circuit 21 and clock input circuit 22 is supplied with an external power supply voltage (VDD) which is a power supply voltage applied from the outside, and is also supplied with an external ground potential (VSS) which is a ground potential on the outside. These circuits operate with the external power supply voltage, and thus include a power supply voltage dependent element (hereinafter referred to as ‘PVDE’) which is an element corresponding to the external power supply voltage.

Command/address input circuit 21 is connected to read/write control circuit 40, and outputs a command signal (CMD) and an address signal (ADD) which are inputted from the outside, to read/write control circuit 40. Clock input circuit 22 is connected to read/write control circuit 40, and outputs a clock signal (CK) inputted from the outside, a signal (/CK) having a potential with a sign opposite to that of the clock signal, and a clock enable signal (CKE), to read/write control circuit 40.

Internal power supply generation circuit 30 is supplied with an external power supply voltage, and is also supplied with an external ground potential. Internal power supply generation circuit 30 includes a PVDE which operates with the external power supply voltage. Internal power supply generation circuit 30 is connected to read/write control circuit 40 via internal power supply voltage (VDD_in) line 32 and internal ground potential (VSS_in) line 33 which are provided in parallel to each other. Internal power supply generation circuit 30 converts the external power supply voltage into an internal power supply voltage, and supplies the internal power supply voltage to read/write control circuit 40 via internal power supply voltage line 32 and internal ground potential line 33.

As illustrated in FIG. 1, internal power supply voltage compensation capacitor (hereinafter referred to as ‘IPVCC’) 31 is provided between internal power supply voltage line 32 and internal ground potential line 33. IPVCC 31 is formed of a common element.

Each of data input/output circuit I/O1 and data input/output circuit I/O2 is connected to VDDQ1 line 42 and VSSQ1 line 43. Data input/output circuit I/O1 is supplied with the external power supply voltage via VDDQ1 line 42, and is supplied with the external ground potential via VSSQ1 line 43. Data input/output circuit I/O1 includes a PVDE which operates with the external power supply voltage. Data input/output circuit I/O1 transmits data DQ1 received from the outside to read/write control circuit 40, and outputs data DQ1 received from read/write control circuit 40 to the outside. It should be noted that each of other data input/output circuits I/O2 to I/O8 has the same structure as that of data input/output circuit I/O1, and hence detailed description thereof is omitted.

Read/write control circuit 40 includes a common element which operates with the internal power supply voltage supplied from internal power supply generation circuit 30. Read/write control circuit 40 selects one of the memory cells included in memory cell array 10 according to the address signal. Further, read/write control circuit 40 writes the data received from the data input/output circuit into the memory cell according to the command signal, or transmits the data read out from the memory cell to the data input/output circuit.

As illustrated in FIG. 1, an external power supply voltage compensation capacitor (hereinafter referred to as ‘EPVCC’) is provided between the VDDQ line for supplying the external power supply voltage to the data input/output circuit and the VSSQ line for supplying the external ground potential to the data input/output circuit. The EPVCC is formed of a PVDE.

FIG. 1 illustrates that EPVCC 41 is provided between VDDQ1 line 421 and VSSQ1 line 431, and EPVCC 41 is provided between VDDQ1 line 424 and VSSQ1 line 434. With regard to other combinations of the VDDQ lines and the VSSQ lines, EPVCC 41 is provided therebetween in the same manner as the structure illustrated in FIG. 1, and illustration of such a structure is omitted in FIG. 1.

Next, the above-mentioned PVDE will be described.

In a case where the PVDE is a MOS (Metal Oxide Semiconductor) transistor, at least one parameter from among parameters that includes the film thickness of a gate oxide film, gate length Lg of a gate electrode, gate width Wg of the gate electrode, and an impurity concentration of a channel is set for the PVDE in accordance with the specifications of the external power supply voltage. In a case where the PVDE is a MOS capacitor, at least one parameter from among parameters that includes the film thickness of a capacitor oxide film, a pattern area of a gate electrode, and an impurity concentration of a channel in a diffusion layer is set for the PVDE in accordance with the specifications of the external power supply voltage.

In the following, for ease of explanation, description is given of the case where the PVDE is a MOS transistor (hereinafter, simply referred to as transistor) unless otherwise defined.

As described above, input circuit 20, data input/output circuits I/O1 to I/O8, internal power supply generation circuit 30, and EPVCC 41 are directly applied with the external power supply voltage. Therefore, these circuits and capacitor can operate stably within a range of the characteristics of the specification by setting at least one of the above-mentioned parameters in accordance with the specifications of the external power supply voltage.

Next, the above-mentioned common element will be described.

In a case where the common element is a transistor, the respective parameters of film thickness of the gate oxide film, gate length Lg, gate width Wg, and the impurity concentration of the channel are commonly set for the common element irrespective of the specifications of the external power supply voltage. In a case where the common element is a MOS capacitor, the respective parameters of film thickness of the capacitor oxide film, the pattern area of the gate electrode, and the impurity concentration of the channel in the diffusion layer are commonly set for the common element.

In the following, for ease of explanation, description will be given of the case where the common element is a transistor unless otherwise defined. As the common element of the present exemplary embodiment, there are two types of elements, that is, an element including a gate oxide film with a thick film thickness and an element including a gate oxide film with a thin film thickness.

As described above, memory cell array 10, read/write control circuit 40, and IPVCC 31 are not directly applied with the external power supply voltage, and hence the common elements which are not dependent on the external power supply voltage are used therefor. The common elements including the gate oxide film having a thin film thickness are used for memory cell array 10 and read/write control circuit 40. On the other hand, either one common element that includes the gate oxide film having a thick film thickness or one common element that includes the gate oxide film having a thin film thickness is used for IPVCC 31 in accordance with the internal power supply voltage generated by internal power supply generation circuit 30.

Next, description will be given of a method of manufacturing the semiconductor memory device in accordance with the specifications of the external power supply voltage. The present exemplary embodiment describes a case where there are two types of external power supply voltages (VDD). It is assumed that the two types of external power supply voltages are VDD=1.8 V and VDD=1.5 V.

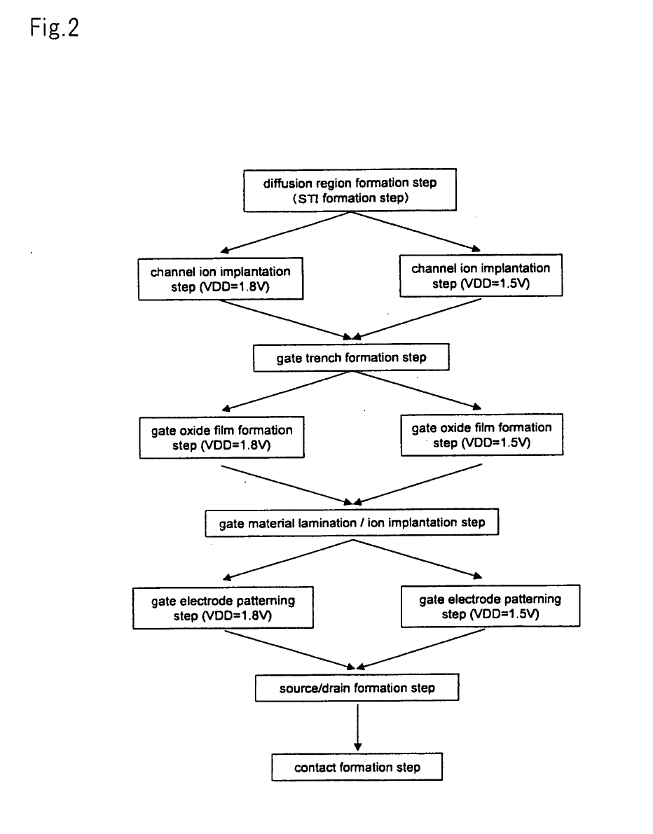

FIG. 2 is a flowchart illustrating a procedure for the method of manufacturing the semiconductor memory device according to the present exemplary embodiment. FIG. 2 illustrates main steps relating to the formation of the PVDE and the common element, and description of the step after the formation of these elements is omitted in FIG. 2.

As illustrated in FIG. 2, in a diffusion region formation step, a gate trench formation step, a gate material lamination/ion implantation step, a source/drain formation step, and a contact formation step, common processes are performed irrespective of the specifications of the external power supply voltage. A process according to the specifications of the external power supply voltage is prepared in advance for each channel ion implantation step, each gate oxide film formation step, and each gate electrode patterning step.

In a case where a semiconductor memory device with a specification of VDD=1.5 V is manufactured on the basis of a manufacturing process for a specification of VDD=1.8 V, a process for the specification of VDD=1.5 V may be selected in at least one of three steps, that is, the channel ion implantation step, the gate oxide film formation step, and the gate electrode patterning step. The process for the specification of VDD=1.5 V may be selected in two or more of these three steps.

Conversely, in a case where a semiconductor memory device with the specification of VDD=1.8 V is manufactured on the basis of the manufacturing process for the specification of VDD=1.5 V, the process for the specification of VDD=1.8 V may be selected in at least one of three steps for which the process according to the specifications of the external power supply voltage is prepared. The process for the specification of VDD=1.8 V may be selected in two or more of these three steps.

It should be noted that the semiconductor memory device of the present exemplary embodiment has a structure including a trench gate type MOS capacitor, and hence the flowchart illustrated in FIG. 2 includes the gate trench formation step. In a case of a semiconductor memory device which does not include a trench gate, the gate trench formation step may be omitted.

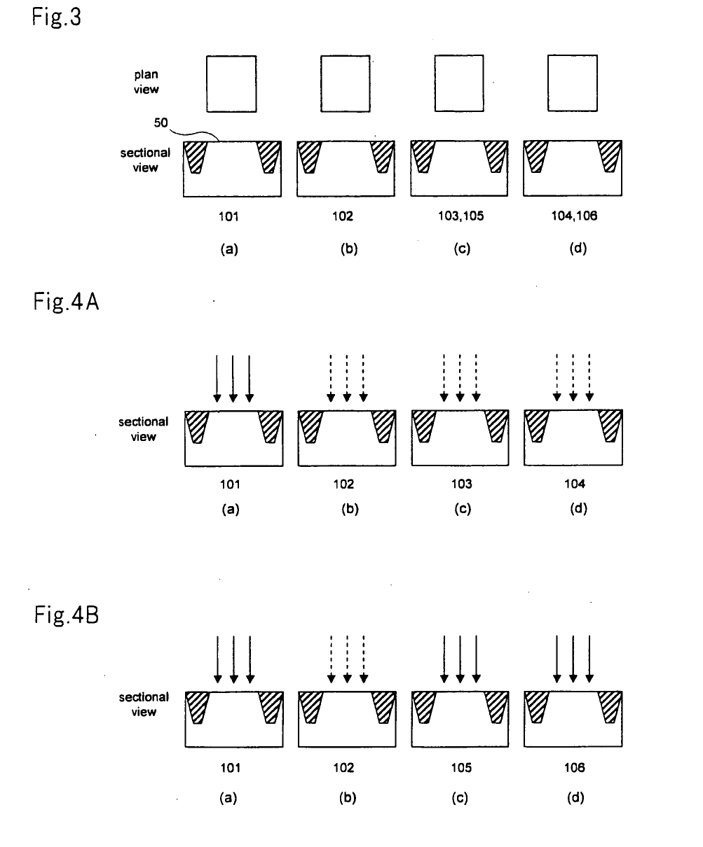

Next, respective steps of the procedure illustrated in FIG. 2 will be described in detail. FIGS. 3 to FIGS. 10B are schematic views illustrating planes and cross sections of the semiconductor memory device in the respective steps of the procedure illustrated in FIG. 2.

Here, description is given in parallel of two cases: a case where all of the three steps, that is, the channel ion implantation step, the gate oxide film formation step, and the gate electrode patterning step are processed in accordance with the specification of VDD=1.8 V; and a case where all of these three steps are processed in accordance with the specification of VDD=1.5 V. The figures each illustrate planes and cross sections of the common element and the PVDE.

The common element is not dependent on the specifications of the external power supply voltage, and there are two types of the common elements, that is, common element 101 including a gate oxide film with a thin film thickness and common element 102 including a gate oxide film with a thick film thickness. Common element 101 and common element 102 are transistors. In the semiconductor memory device with the specification of VDD=1.8 V, PVDEs 103 and 104 each including a gate oxide film with a thick film thickness are used. PVDE 103 is a transistor, and PVDE 104 is a MOS capacitor. The MOS capacitor functions as EPVCC 41 illustrated in FIG. 1.

In the semiconductor memory device with the specification of VDD=1.5 V, PVDEs 105 and 106 each including a gate oxide film with a thin film thickness are used. PVDE 105 is a transistor, and PVDE 106 is a MOS capacitor. The MOS capacitor functions as EPVCC 41 illustrated in FIG. 1.

First, the diffusion region formation step illustrated in FIG. 2 will be described. FIG. 3 are plan views and cross sectional views of the semiconductor memory device, for describing the diffusion region formation step.

FIG. 3(a) is a plan view and sectional view of common element 101. FIG. 3(b) is a plan view and sectional view of common element 102. FIG. 3(c) is a plan view and sectional view of each of PVDEs 103 and 105. FIG. 3(d) is a plan view and sectional view of each of PVDEs 104 and 106.

The step illustrated in FIG. 3 is a step of forming diffusion region 50 which is to serve as a formation region of the transistor, and is common to both the common element and the PVDE. FIG. 3 illustrate the planes and the cross sections of the semiconductor memory device after the formation of the diffusion region.

In this step, an STI (Shallow Trench Isolation) is formed in the vicinity of a surface of a substrate, to thereby form diffusion region 50 surrounded by the STI. Diffusion region 50 may be a region obtained by sectioning the substrate into which conductive impurities are diffused in advance, or may be a region obtained by sectioning a well which is formed by diffusing conductive impurities from the surface of the substrate to a predetermined depth. Diffusion region 50 corresponds to an element formation region. It should be noted that the diffusion region formation step is also referred to as an STI formation step.

Subsequently, the channel ion implantation step illustrated in FIG. 2 is described. FIG. 4A and FIG. 4B are cross sectional views of the semiconductor memory device, for describing the channel ion implantation step. It should be noted that a patterning process is not performed in this step, so that the planar shape of the semiconductor memory device is the same as the planes illustrated in FIG. 3, and hence plan views thereof are omitted.

FIG. 4A illustrate the channel ion implantation step in the semiconductor memory device having the specification of VDD=1.8 V. FIG. 4A(a) is a sectional view of common element 101. FIG. 4A(b) is a sectional view of common element 102. FIG. 4A(c) is a sectional view of PVDE 103. FIG. 4A(d) is a sectional view of PVDE 104.

FIG. 4B illustrate the channel ion implantation step in the semiconductor memory device having the specification of VDD=1.5 V. FIG. 4B(a) is a sectional view of common element 101. FIG. 4B(b) is a sectional view of common element 102. FIG. 4B(c) is a sectional view of PVDE 105. FIG. 4B(d) is a sectional view of PVDE 106.

Solid arrows and dashed arrows in FIG. 4A and FIG. 4B indicate a difference in the amount of impurity ion implantation into the channel. There is a difference between the amount of impurities implanted into the formation region of the element having the thick gate oxide film and the amount of impurities implanted into the formation region of the element having the thin gate oxide film.

Here, a relationship among the film thickness of the gate oxide film, the threshold voltage, and the channel concentration of the transistor is briefly described.

The same amount of channel ion implantation is performed on the transistor that includes the gate oxide film that has a thick film thickness as well as the transistor that includes the gate oxide film that has a thin film thickness. In this case, the channel concentrations in the vicinities of the surfaces of the diffusion layers are equivalent to each other, and on the other hand, the threshold voltage of the transistor that includes the gate oxide film that has a thick film thickness is larger than that of the transistor that includes the gate oxide film that has a thin film thickness. In order to make the threshold voltages of these two types of transistors equivalent, the implantation amount of impurities into the channel may be made larger in the transistor that includes the gate oxide film that has a thick film thickness than in the transistor that includes the gate oxide film that has a thin film thickness.

FIG. 4A and FIG. 4B illustrate that the implantation amount of impurities is adjusted depending on the film thickness of the gate oxide film so that the transistor that includes the gate oxide film that has a thick film thickness and the transistor that includes the gate oxide film that has a thin film thickness have the equivalent threshold voltage irrespective of the level of the external power supply voltage.

In a case where it is desired that the channel concentration is different for each element formation region, as in the present exemplary embodiment, ion implantation is performed multiple times by using a resist mask which covers the region into which the impurities are not implanted. For example, FIG. 4A describe a case where the channel concentrations of common element 102 and PVDEs 103 and 104 are made higher than that of common element 101. Impurities at the amount that is to be implanted into common element 101 are implanted into all of these element formation regions. Subsequently, at least the element formation region of common element 101 is covered by a resist mask, and then the remaining amount of impurities are implanted into the element formation regions of common element 102 and PVDEs 103 and 104.

In this way, the relationship among the film thickness of the gate oxide film, the threshold voltage, and the channel concentration of the transistor is determined in advance, and the channel ion implantation step is controlled by setting the amount of impurity ion implantation so that a desired threshold voltage can be obtained for each transistor, whereby it becomes possible to form an element having a threshold voltage in accordance with the specifications of the external power supply voltage.

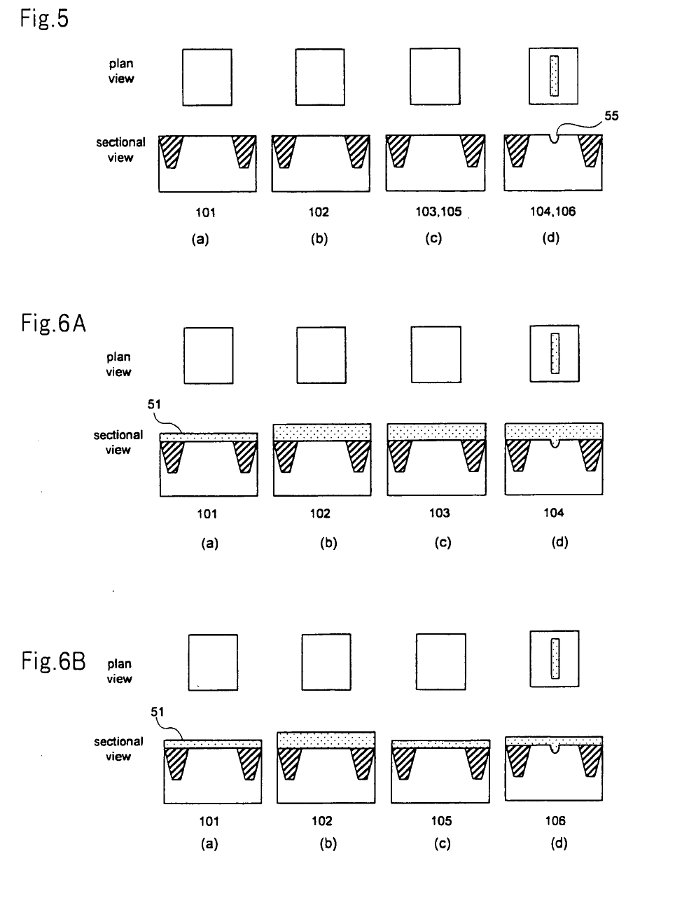

FIG. 5 are plan views and cross sectional views of the semiconductor memory device, for describing the gate trench formation step. Because the gate trench formation step is common to the specification of VDD=1.8 V and the specification of VDD=1.5 V, illustrations corresponding to each specification are omitted in FIG. 5.

FIG. 5(a) is a plan view and sectional view of common element 101. FIG. 5(b) is a plan view and sectional view of common element 102. FIG. 5(c) is a plan view and sectional view of each of PVDEs 103 and 105. FIG. 5(d) is a plan view and sectional view of each of PVDEs 104 and 106.

A process of forming a trench on the surfaces of the formation regions of PVDEs 104 and 106 is common to both the specification of VDD=1.8 V and the specification of VDD=1.5 V. As illustrated in FIG. 5, the surfaces of the formation regions of PVDEs 104 and 106 are selectively etched, to thereby form trench 55.

Next, the gate oxide film formation step will be described.

FIG. 6A and FIG. 6B are plan views and cross sectional views of the semiconductor memory device, for describing the gate oxide film formation step.

FIG. 6A illustrate the gate oxide film formation step in the semiconductor memory device having the specification of VDD=1.8 V. FIG. 6A(a) is a plan view and sectional view of common element 101. FIG. 6A(b) is a plan view and sectional view of common element 102. FIG. 6A(c) is a plan view and sectional view of PVDE 103. FIG. 6A(d) is a plan view and sectional view of PVDE 104.

FIG. 6B illustrate the gate oxide film formation step in the semiconductor memory device having the specification of VDD=1.5 V. FIG. 6B(a) is a plan view and sectional view of common element 101. FIG. 6B(b) is a plan view and sectional view of common element 102. FIG. 6B(c) is a plan view and sectional view of PVDE 105. FIG. 6B(d) is a plan view and sectional view of PVDE 106.

The thin gate oxide film and the thick gate oxide film are formed by a two-stage oxidation process as described below. In the following, a region in which the gate oxide film that has a thin film thickness is formed is referred to as a thin film formation region, and a region in which the gate oxide film that has a thick film thickness is formed is referred to as a thick film formation region. First, a thermal oxidation process as a first stage is performed, to thereby form a thin oxide film on surfaces of both the thin film formation region and the thick film formation region. Subsequently, the thin film formation region is covered by an antioxidant mask, and then a thermal oxidation process as a second stage is performed, to thereby make thicker the film thickness of the oxide film formed on the surface of the thick film formation region. After that, the antioxidant mask is removed. An example of the antioxidant mask includes an Si₃N₄ film.

The region which is covered by the antioxidant mask before performing the thermal oxidation process as the second stage is different between the semiconductor memory device having the specification of VDD=1.8 V and the semiconductor memory device having the specification of VDD=1.5 V. In the case of the specification of VDD=1.8 V in FIG. 6A, after the first thermal oxidation process, the formation region of common element 101 is covered by the antioxidant mask, and the second thermal oxidation process is performed. In the case of the specification of VDD=1.5 V in FIG. 6B, after the first thermal oxidation process, the formation regions of common element 101 and PVDEs 105 and 106 are covered by the antioxidant mask, and the second thermal oxidation process is performed.

The larger the voltage which is applied from the outside to the gate electrode is, it is desirable that, the thicker the film thickness of the gate oxide film is, in view of the insulation voltage between the gate electrode and the diffusion region. In addition, when the channel concentrations are the same, the thicker the film thickness of the gate oxide film is, the larger the threshold voltage becomes. Further, when the film thicknesses of the gate oxide films are different, the I (current)-V (voltage) characteristics of the transistor are different. The gate oxide film formation step is controlled so that desired I-V characteristics and a desired threshold voltage can be obtained for each transistor, whereby it becomes possible to form an element having electrical characteristics in accordance with the specifications of the external power supply voltage.

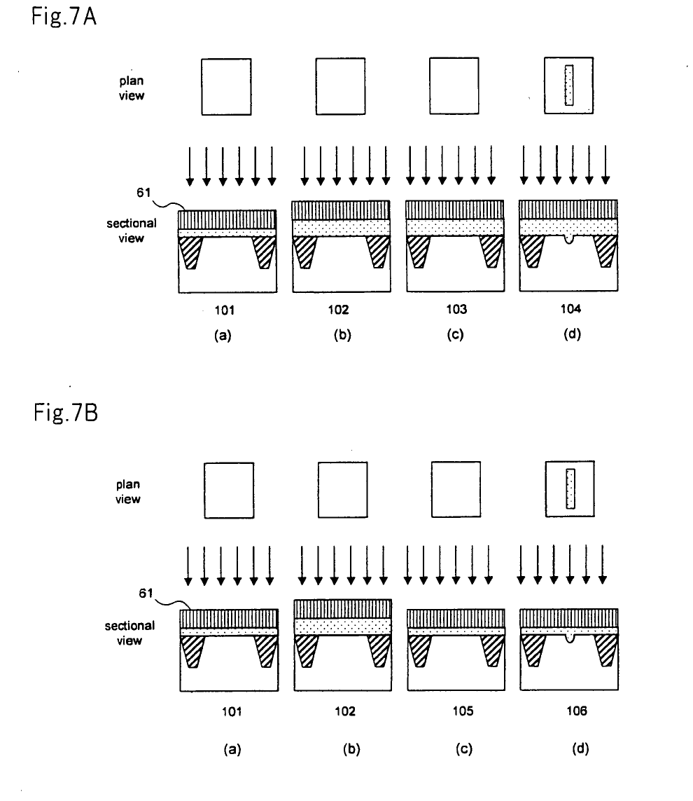

FIG. 7A and FIG. 7B are plan views and cross sectional views of the semiconductor memory device, for describing the gate material lamination/ion implantation step.

FIG. 7A illustrate the gate material lamination/ion implantation step in the semiconductor memory device having the specification of VDD=1.8 V. FIG. 7A(a) is a plan view and sectional view of common element 101. FIG. 7A(b) is a plan view and sectional view of common element 102. FIG. 7A(c) is a plan view and sectional view of PVDE 103. FIG. 7A(d) is a plan view and sectional view of PVDE 104.

FIG. 7B illustrate the gate material lamination/ion implantation step in the semiconductor memory device having the specification of VDD=1.5 V. FIG. 7B(a) is a plan view and sectional view of common element 101. FIG. 7B(b) is a plan view and sectional view of common element 102. FIG. 7B(c) is a plan view and sectional view of PVDE 105. FIG. 7B(d) is a plan view and sectional view of PVDE 106.

A process of forming a conductive film which is to serve as the gate electrode of each of the elements is common to both the specification of VDD=1.8 V and the specification of VDD=1.5 V. As illustrated in FIG. 7A and FIG. 7B, gate material 61 is formed on the gate oxide film so as to have a predetermined film thickness. An example of gate material 61 includes a polysilicon film. The polysilicon film is formed by, for example, a CVD (Chemical Vapor Deposition) method. After gate material 61 is formed on the gate oxide film, conductive impurities are introduced into gate material 61 by an ion implantation process. Arrows illustrated in FIG. 7A and FIG. 7B indicate the implantation of impurity ions. The conductive impurities are diffused into gate material 61 by a subsequent thermal process.

Next, the gate electrode patterning step will be described.

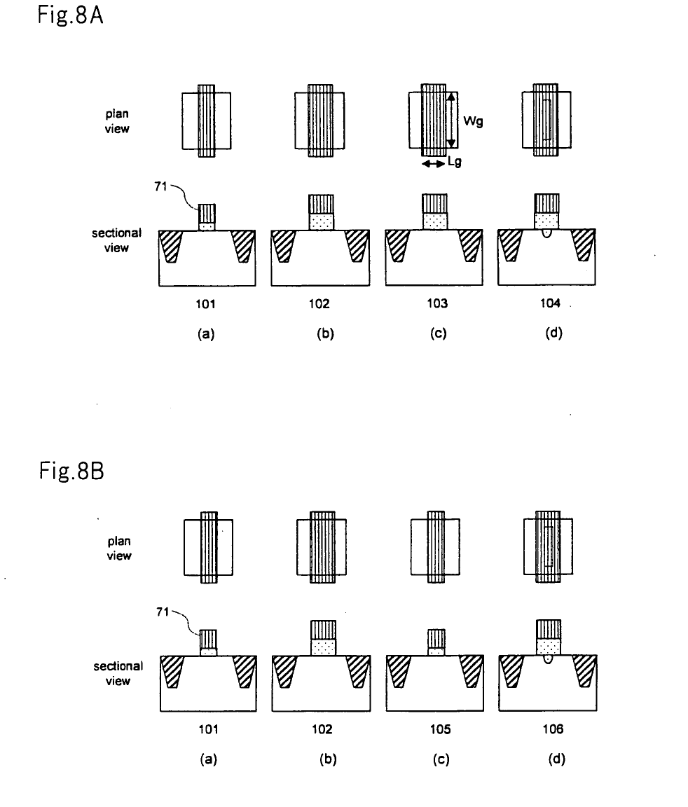

FIG. 8A and FIG. 8B are plan views and cross sectional views of the semiconductor memory device, for describing the gate electrode patterning step.

FIG. 8A illustrate the gate electrode patterning step in the semiconductor memory device having the specification of VDD=1.8 V. FIG. 8A(a) is a plan view and sectional view of common element 101. FIG. 8A(b) is a plan view and sectional view of common element 102. FIG. 8A(c) is a plan view and sectional view of PVDE 103. FIG. 8A(d) is a plan view and sectional view of PVDE 104.

FIG. 8B illustrate the gate electrode patterning step in the semiconductor memory device having the specification of VDD=1.5 V. FIG. 8B(a) is a plan view and sectional view of common element 101. FIG. 8B(b) is a plan view and sectional view of common element 102. FIG. 8B(c) is a plan view and sectional view of PVDE 105. FIG. 8B(d) is a plan view and sectional view of PVDE 106.

A resist is applied onto gate material 61 illustrated in FIG. 7A and FIG. 7B, and then a pattern of a photomask is transferred to the resist, to thereby form a resist mask. After that, etching is performed on gate material 61 from above the resist mask, to thereby form gate electrode 71 illustrated in FIG. 8A and FIG. 8B. In this step, a plurality of types of photomasks on which a gate electrode pattern is drawn are prepared in advance, and a photomask is selected from the plurality of types of photomasks in accordance with the specifications of the external power supply voltage. As described above, the subsequent process is common irrespective of the specifications of the external power supply voltage. In the following, the relationship between the gate electrode pattern drawn on the photomask and the electrical characteristics of the transistor will be described.

Gate length Lg and gate width Wg of the gate electrode are described by taking PVDE 103 illustrated in FIG. 8A as an example. Gate length Lg is a length of the gate electrode pattern in a direction in which a channel current flows between a source electrode and a drain electrode when the transistor is turned on. Gate width Wg is a length of the pattern covering the diffusion region via the gate oxide film, in a direction perpendicular to gate length Lg.

The shorter gate length Lg is and the longer gate width Wg is, the lower the threshold voltage of the transistor becomes. In addition, when at least one of gate length Lg and gate width Wg is changed, the I-V characteristics of the transistor are also changed.

In the present exemplary embodiment, in the case of the specification of VDD=1.8 V, as illustrated in FIG. 8A, the lengths of gate widths Wg of the respective elements are made equal, and gate length Lg of common element 101 is made shorter than those of common element 102 and PVDEs 103 and 104. In the case of the specification of VDD=1.5 V, as illustrated in FIG. 8B, the lengths of gate widths Wg of the respective elements are made equal similarly to the specification of VDD=1.8 V, but gate lengths Lg of common element 102 and PVDE 106 are made longer than those of common element 101 and PVDE 105. Gate length Lg of the gate electrode is set to be different between PVDE 103 having the specification of VDD=1.8 V and PVDE 105 having the specification of VDD=1.5 V.

It should be noted that gate lengths Lg of PVDEs 104 and 106 which are MOS capacitors may be changed between the specification of VDD=1.8 V and the specification of VDD=1.5 V. However, because gate lengths Lg set therefor are long, gates length Lg may not be changed in accordance with the specifications of the external power supply voltage as in the present exemplary embodiment.

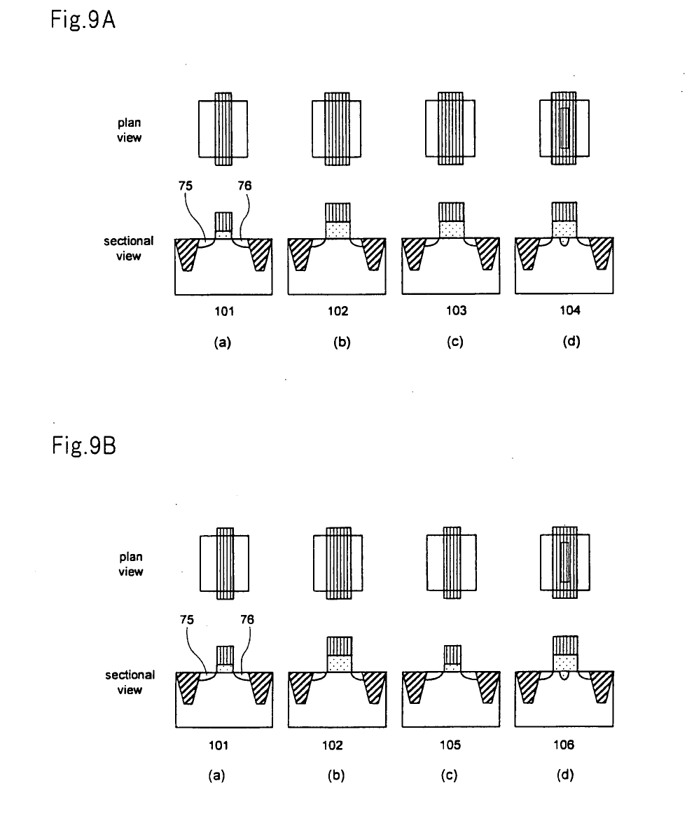

FIG. 9A and FIG. 9B are plan views and cross sectional views of the semiconductor memory device, for describing the source/drain formation step.

FIG. 9A illustrate the source/drain formation step in the semiconductor memory device having the specification of VDD=1.8 V. FIG. 9A(a) is a plan view and sectional view of common element 101. FIG. 9A(b) is a plan view and sectional view of common element 102. FIG. 9A(c) is a plan view and sectional view of PVDE 103. FIG. 9A(d) is a plan view and sectional view of PVDE 104.

FIG. 9B illustrate the source/drain formation step in the semiconductor memory device having the specification of VDD=1.5 V. FIG. 9B(a) is a plan view and sectional view of common element 101. FIG. 9B(b) is a plan view and sectional view of common element 102. FIG. 9B(c) is a plan view and sectional view of PVDE 105. FIG. 9B(d) is a plan view and sectional view of PVDE 106.

A process of forming the source electrode and the drain electrode of the transistor is common to both the specification of VDD=1.8 V and the specification of VDD=1.5 V. After the gate electrode patterning step illustrated in FIG. 8A and FIG. 8B, ion implantation of conductive impurities is performed on the diffusion region with gate electrode 71 being used as a mask. The conductive impurities are diffused from the surface of the diffusion layer toward a deeper part by the subsequent thermal process, so that source electrode 75 and drain electrode 76 are formed as illustrated in FIG. 9A and FIG. 9B.

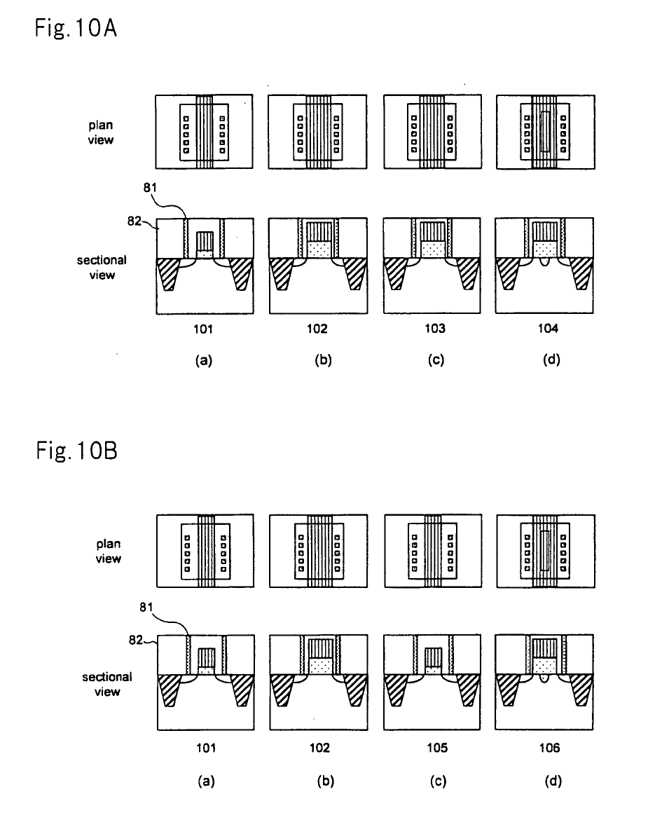

FIG. 10A and FIG. 10B are plan views and cross sectional views of the semiconductor memory device, for describing the contact formation step.

FIG. 10A illustrate the contact formation step in the semiconductor memory device having the specification of VDD=1.8 V. FIG. 10A(a) is a plan view and sectional view of common element 101. FIG. 10A(b) is a plan view and sectional view of common element 102. FIG. 10A(c) is a plan view and sectional view of PVDE 103. FIG. 10A(d) is a plan view and sectional view of PVDE 104.

FIG. 10B illustrate the contact formation step in the semiconductor memory device having the specification of VDD=1.5 V. FIG. 10B(a) is a plan view and sectional view of common element 101. FIG. 10B(b) is a plan view and sectional view of common element 102. FIG. 10B(c) is a plan view and sectional view of PVDE 105. FIG. 10B(d) is a plan view and sectional view of PVDE 106.

A step of forming contacts in the source electrode and the drain electrode is common to both the specification of VDD=1.8 V and the specification of VDD=1.5 V. After the source/drain formation step illustrated in FIG. 9A and FIG. 9B, interlayer insulating film 82 is formed on the surface of the substrate. Subsequently, interlayer insulating film 82 is selectively etched to form an opening for a contact pattern, and a conductive material is embedded into the opening, so that contact 81 is formed as illustrated in FIG. 10A and FIG. 10B. Detailed description of the subsequent step is omitted.

With reference to FIG. 10A and FIG. 10B, it is understood that insulation between the gate electrode and the contact is secured in elements such as common element 102 having long gate length Lg. In the following, even when gate length Lg is changed in accordance with the specifications of the external power supply voltage, a method of securing the insulation between the gate electrode and the contact will be described.

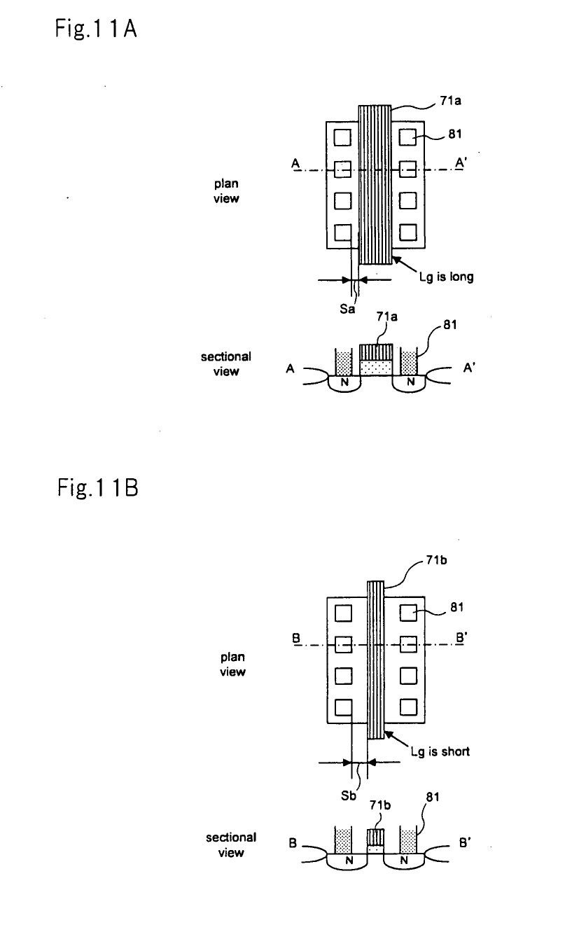

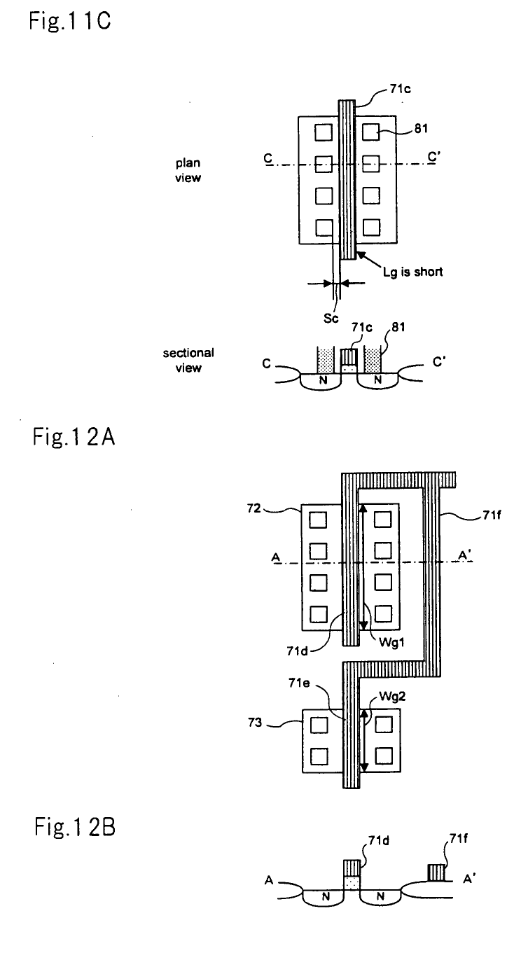

FIG. 11A to FIG. 11C are schematic views illustrating a positional relation between the gate electrode and the contact. FIG. 11A illustrates a plane and a cross section of the PVDE having the specification of VDD=1.8 V. FIG. 11B illustrates a plane and a cross section of the PVDE having the specification of VDD=1.5 V. FIG. 11C illustrates a plane and a cross section of the common element which is not dependent on the specifications of the power supply voltage. In FIG. 11A to FIG. 11C, an element isolation portion is represented by a field oxide film, but may be an STI instead.

The lower part of FIG. 11A illustrates the cross section taken along the line A-A′ of the plan view in the upper part thereof. The lower part of FIG. 11B illustrates the cross section taken along the line B-B′ of the plan view in the upper part thereof. The lower part of FIG. 11C illustrates the cross section taken along the line C-C′ of the plan view in the upper part thereof.

With regard to an interval between the gate electrode and the contact, the PVDE having the specification of VDD=1.5 V and the common element having the specification of VDD=1.5 V are compared. In comparison between FIG. 11B and FIG. 11C, interval Sb between gate electrode 71b and contact 81 of the PVDE is wider than interval Sc between gate electrode 71c and contact 81 of the common element. This is because it is thought that, in the PVDE, gate length Lg may be long in accordance with the power supply voltage, and accordingly the interval between the gate electrode and the contact is set to be sufficiently wide so that the gate electrode and the contact are not brought into contact with each other even when length Lg becomes long.

As is apparent from the PVDE illustrated in FIG. 11A, gate length Lg of the PVDE illustrated in FIG. 11A is longer than that of the PVDE illustrated in FIG. 11B, but space Sa is secured between gate electrode 71a and contact 81, so that gate electrode 71a and contact 81 are electrically insulated.

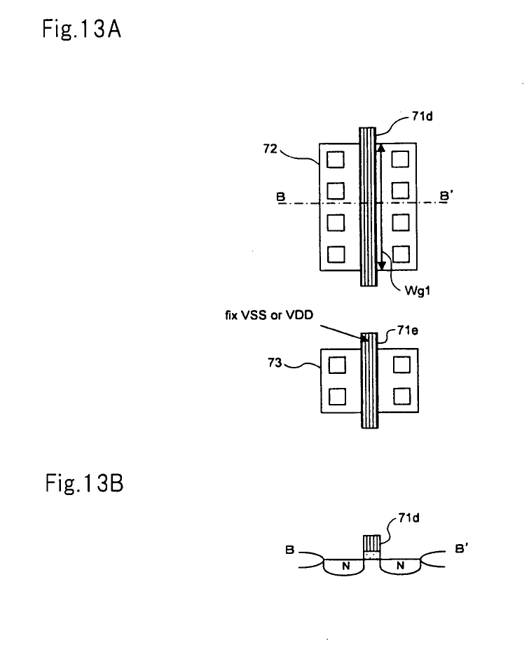

Next, description is given of an example of a method of changing gate width Wg of the gate electrode in the gate electrode patterning step. FIG. 12A and FIG. 12B are a plan view and a cross sectional view illustrating a case where the gate width is long, respectively. FIG. 12B illustrates a cross section taken along the line A-A′ of FIG. 12A. FIG. 13A and FIG. 13B are a plan view and a cross sectional view illustrating a case where the gate width is short, respectively. FIG. 13B illustrates a cross section taken along the line B-B′ of FIG. 13A.

A transistor illustrated in FIG. 12A and FIG. 12B has a structure in which transistor 72 and transistor 73 are connected in parallel. Gate electrode 71d and gate electrode 71e are connected by gate electrode 71f. Although not illustrated, drain electrodes of transistor 72 and transistor 73 are connected by common wiring, and source electrodes of these two transistors are connected by common wiring. Gate width Wg of the transistor illustrated in FIG. 12A is equal to the sum of gate width Wg1 and gate width Wg2.

On the other hand, in FIG. 13A and FIG. 13B, gate electrode 71e of transistor 73 and gate electrode 71d of transistor 72 are not connected to each other. In order not to operate transistor 73, gate electrode 71e is supplied with the ground potential (VSS) or the power supply potential (VDD). In FIG. 13A, transistor 72 operates alone, and hence gate width Wg of the transistor is equal to gate width Wg1 alone.

Comparison between the transistor of FIG. 12A and the transistor of FIG. 13A reveals that the gate width of the transistor illustrated in FIG. 12A is wider by gate width Wg2 than that of the transistor illustrated in FIG. 13A. Accordingly, if conditions other than the gate width are the same, when the respective elements are applied with an equal voltage, a larger amount of source-drain current flows through the transistor illustrated in FIG. 12A than through the transistor illustrated in FIG. 13A.

It should be noted that, in the present exemplary embodiment, for the method of changing gate width Wg of the transistor, description has been given of the case where the number of transistors which can be connected in parallel is two. Alternatively, the number of transistors which can be connected in parallel may be three or more. In this case, gate width Wg is made smaller for each transistor to increase the number of transistors which can be connected in parallel, whereby the option for the number of transistors to be connected in parallel is increased, which enables fine adjustment of the source-drain current.

With reference to FIG. 8A and FIG. 8B, an example of the method of changing gate length Lg of the gate electrode has been described, but as has been described with reference to FIG. 12A to FIG. 13B, it is also possible to change gate width Wg of the gate electrode in the gate electrode patterning step in accordance with the specifications of the external power supply voltage.

According to the method of manufacturing the semiconductor device of the present exemplary embodiment, in a case of manufacturing: a first semiconductor device which operates by being supplied with a first power supply voltage from the outside; and a second semiconductor device which operates by being supplied with a second power supply voltage that is different from the first power supply voltage from the outside, at least the diffusion region formation step is commonly performed instead of individually manufacturing, from the beginning, the semiconductor devices which operate with power supply voltages that are different from each other. As a result, the manufacturing process therefor can be prevented from becoming complicated, and an increase in the cost of development and the cost of manufacturing can be suppressed.

In addition, at least one step from among the channel ion implantation step, the gate oxide film formation step, and the gate electrode patterning step is performed according to a step of forming an element which operates with the first power supply voltage in the case of manufacturing the first semiconductor device, and is performed according to a step of forming an element which operates with the second power supply voltage in the case of manufacturing the second semiconductor device. This eliminates the need to fabricate within one semiconductor device a plurality of circuits which operate with power supply voltages that are different from each other, and hence an increase in area of the semiconductor device can be suppressed.

As described above, according to the present exemplary embodiment, in the case of manufacturing either the first semiconductor device or the second semiconductor device, at least the diffusion region formation step may be commonly performed, and at least one step from among the above-mentioned three steps may be performed according to the step of forming the element which operates with the power supply voltage supplied from the outside. Therefore, the manufacturing process therefor can be prevented from becoming complicated, and moreover it is possible to eliminate the need to fabricate within one semiconductor device a plurality of circuits which operate with power supply voltages that are different from each other. As a result, an increase in the cost of development and the cost of manufacturing can be suppressed, and an increase in area of the semiconductor device can also be suppressed.

It is apparent that the present invention is not limited to the above embodiments, but may be modified and changed without departing from the scope and spirit of the invention.

What is claimed is:

1. A method of manufacturing a semiconductor device, comprising:
commonly performing at least diffusion region formation in a case of manufacturing a first semiconductor device which operates by being supplied with a first power supply voltage from an outside and in a case of manufacturing a second semiconductor device which operates by being supplied with a second power supply voltage from the outside, the second power supply voltage being different from the first power supply voltage;
performing, in the case of manufacturing the first semiconductor device, at least one step from among channel ion implantation, gate oxide film formation, and gate electrode patterning according to a process of forming an element which operates with the first power supply voltage; and
performing, in the case of manufacturing the second semiconductor device, at least one step from among the channel ion implantation, the gate oxide film formation, and the gate electrode patterning according to a process of forming an element which operates with the second power supply voltage.

2. The method of manufacturing a semiconductor device according to claim 1, wherein the channel ion implantation comprises implanting, into a diffusion region, conductive impurities at an implantation amount corresponding to a channel concentration of either the element which operates with the first power supply voltage or the element which operates with the second power supply voltage.

3. The method of manufacturing a semiconductor device according to claim 1, wherein the gate oxide film formation comprises forming a gate oxide film having a film thickness with an insulation voltage for either the element which operates with the first power supply voltage or the element which operates with the second power supply voltage.

4. The method of manufacturing a semiconductor device according to claim 1, wherein the gate electrode patterning comprises forming a gate electrode having either a gate length or a gate width of either the element which operates with the first power supply voltage or the element which operates with the second power supply voltage.

5. The method of manufacturing a semiconductor device according to claim 4, wherein the gate electrode patterning further comprises, as a method of changing the gate width of either the element which operates with the first power supply voltage or the element which operates with the second power supply voltage, changing the number of transistors connected in parallel.

6. The method of manufacturing a semiconductor device according to claim 1, wherein the channel ion implantation, the gate oxide film formation, and the gate electrode patterning comprise forming an element which is common to the first semiconductor device and the second semiconductor device, the element being not dependent on a power supply voltage supplied from the outside.

7. A method manufacturing a semiconductor device, the method comprising:
selectively forming a plurality of active areas in a semiconductor substrate;
implanting a first impurity into the active areas of the semiconductor substrate to form channel doped layers respectively in the active areas;
forming a gate insulating film on the semiconductor substrate; and
forming a plurality of gate electrodes on the gate insulating film, each of the gate electrodes being arranged above a corresponding one of the active areas;
wherein the selectively forming the plurality of active areas, when the semiconductor device is configured to operate on a first power supply voltage, is substantially equal to the selectively forming the plurality of active areas, when the semiconductor device is configured to operate on a second power supply voltage which is higher than the first power supply voltage, and while at least one of the implanting the first impurity, the forming the gate insulating film and the forming the gate electrodes, when the semiconductor device is configured to operate on the first power supply voltage, is different from the at least one of the implanting the first impurity, the forming the gate insulating film and the forming the gate electrodes, when the semiconductor device is configured to operate on the second power supply voltage.

8. The method as claimed in claim 7, wherein the first impurity implanted in the implanting, when the semiconductor device is configured to operate on the first power supply voltage, is lower in amount than the first impurity implanted in the implanting, when the semiconductor device is configured to operate on the second power supply voltage.

9. The method as claimed in claim 7, wherein the gate insulating film formed in the forming the gate insulating film, when the semiconductor device is configured to operate on the first power supply voltage, is thinner in thickness than the gate insulating film formed in the forming the gate insulating film, when the semiconductor device is configured to operate on the second power supply voltage.

10. The method as claimed in claim 7, wherein each of the gate electrodes formed in the forming the plurality of gate electrodes, when the semiconductor device is configured to operate on the first power supply voltage is shorter in length than each of the gate electrodes formed in the forming the plurality of gate electrode, when the semiconductor device is configured to operate on the second power supply voltage.

11. A method manufacturing a semiconductor device, the method comprising:
selectively forming a plurality of active areas in a semiconductor substrate, the forming the active areas being performed irrespective of a variation of a power supply voltage on which the semiconductor device being configured to operate; and
forming a plurality of transistors respectively in the active areas, the forming the transistors being performed according to the variation of the power supply voltage on which the semiconductor device being configured to operate.

12. The method as claimed in claim 11, wherein the forming the transistors includes;
implanting a first impurity into the active areas of the semiconductor substrate to form channel doped layers respectively in the active areas,
forming a gate insulating film on the semiconductor substrate, and
forming a plurality of gate electrodes on the gate insulating film, each of the gate electrodes being arranged above a corresponding one of the active areas, and
at least one of the implanting the first impurity, the forming the gate insulating film and the forming the gate electrodes is performed according to the variation of the power supply voltage on which the semiconductor device being configured to operate.

13. The method as claimed in claim 12, wherein an amount of the first impurity implanted in the implanting varies according to the variation of the power supply voltage on which the semiconductor device being configured to operate.

14. The method as claimed in claim 12, wherein a thickness of the gate insulating film formed in the forming the gate insulating film varies according to the variation of the power supply voltage on which the semiconductor device being configured to operate.

15. The method as claimed in claim 12, wherein a channel length of each of the gate electrodes formed in the forming the gate electrodes varies according to the variation of the power supply voltage on which the semiconductor device being configured to operate.
